(19) United States
(12) Patent Application Publication
(10) Pub. No.: US 2013/0107462 A1
(43) Pub. Date: May 2, 2013

(54) HIDDEN PIN TYPE HIGH-POWER LED SUPPORT AND HIDDEN PIN TYPE HIGH-POWER LED PACKAGING STRUCTURE AND TECHNOLOGY USING SAME

(71) Applicants: Zhirong LU, Shenzhen (CN); Yongzhi HUANG, Shenzhen (CN)

(72) Inventors: Zhirong LU, Shenzhen (CN); Yongzhi HUANG, Shenzhen (CN)

(21) Appl. No.: 13/350,868

(22) Filed: Jan. 16, 2012

(30) Foreign Application Priority Data
Oct. 27, 2011 (CN) 201110348509.1

(51) Int. Cl. H05K 7/20

(52) U.S. Cl. 361/709

(57) ABSTRACT

The invention discloses a hidden pin type high-power LED support, which comprises conductive pins and a base for packing the conductive pins, wherein a cavity is formed on the top of the base; a heat sink is fixedly arranged at the bottom of the cavity; the conductive pins pass through the bottom surface of the base; and the bottom surfaces of the conductive pins are parallel and level to the bottom surfaces of the base and the heat sink. The high-power LED support provided by the invention realizes the subsequent automated production of LEDs through a vibration plate smoothly by successfully hiding the conductive pins extended to both sides of an imitated Lumen lamp bead in the prior art in a frame of the base. Moreover, the invention also discloses high-power LED packaging structure and technology using same.

### FIELD OF THE INVENTION

The invention relates to a high-power LED support, in particular to a hidden pin type high-power LED support. Moreover, the invention also discloses high-power LED packaging structure and technology using same.

### BACKGROUND OF THE INVENTION

As white light emitting diodes have the advantages of high efficiency, long service life, high reliability, environmental protection, energy saving, flexible application, etc., the white light emitting diodes are widely recognized as a fourth generation of illuminated light sources and have broad development prospect. There are mainly four available LED light sources in the market, namely imitated Lumen type, stamp-mounting-paper (SMD) type, integrated high-power type and LAMP type.

The LAMP type LEDs are pin type lamp beads, can only be used as low-power lamp beads as the heat dissipation of the LAMP type LEDs mainly depends on pins, and are mainly applied to products such as decorative lamps, low-power portable lamps and simple display screens.

The SMD LEDs are limited by the small heat dissipation area of supports and can only be used for low-power packaging. For example, main products 3528, 5050, etc. can only achieve the maximum power of 0.2 W. In the case of the production of high-power lamps, the only solution is to use the modular arrays of lamp beads in the later period. However, the lamps produced by the method have low efficiency.

Currently, the imitated Lumen type LEDs and the integrated high-power type LEDs are the main light sources for producing high-power lamps, wherein the imitated Lumen type LEDs are mainly used for producing high-power lamp beads with the power of 1 W or more than 1W, and the imitated Lumen type lamp beads dominate the high-power LED illumination market. As illustrated in FIG. 1, an imitated Lumen type LED comprises a base 200, a chip fixed inside the base 200, a lens 500 for covering the chip, and conductive pins 200a and 200b which are extended from both sides of the base 200. However, the imitated Lumen type LED is limited by the exposed structure of the conductive pins 200a and 200b and cannot realize the automated production. In the light splitting process in the later period, due to the exposed structure of the conductive pins 200a and 200b, the LED cannot pass through an automatic vibration plate and can only be manually packed into a feed pipe, mounted on a light splitting device for light splitting, packed into the feed pipe again after light splitting, and finally placed in a braider for braiding. The whole process can only be completed by manual work. Moreover, the process for producing the lens is fussy and requires a lot of labor hours. Therefore, the imitated Lumen type LED has the disadvantages of fussy production process, incapability of achieving the comprehensive automated production, low production efficiency and high price. All the disadvantages are technical problems for limiting the promotion of the imitated Lumen type LEDs.

The integrated high-power type LEDs cannot be subjected to standardized production due to the lack of industry standards and can only be customized in light of the requirements of the available application manufacturers. Moreover, the integrated high-power type LEDs have the disadvantages of low universality, large volume, complex structure, fussy processes and low production efficiency, and cannot be subjected to automated production as well.

### SUMMARY OF THE INVENTION

The invention first aims to provide a hidden pin type LED support capable of realizing the automated packaging of a high-power LED lamp bead in order to solve the technical problems in the high-power LED production in the prior art.

In order to achieve the aim, the technical proposal adopted by the invention is as follows: the invention provides a hidden pin type high-power LED support, which comprises conductive pins and a base for packing the conductive pins; a cavity is formed on the top of the base; a heat sink is fixedly arranged at the bottom of the cavity; the conductive pins pass through the bottom surface of the base; and the bottom surfaces of the conductive pins are parallel and level to the bottom surfaces of the base and the heat sink.

The so-called “hidden pin type” of the invention refers to that the conductive pins are hidden in a frame of the base. The high-power LED support provided by the invention successfully hides the conductive pins extended to both sides of an imitated Lumen lamp bead in the prior art in the frame of the base and hides exposed flangings of the conductive pins at the bottom of the base, so that the subsequent automated LED production can be smoothly realized through a vibration plate. The high-power LED support has skillful structural design, solves the long-term technical problem in the field that the comprehensive automated production of high-power LEDs cannot be realized, completely breaks through the traditional semiautomatic high-power LED packaging mode, promotes the automated packaging process of the entire industry, and is a new revolutionary breakthrough in the field of high-power LED packaging. The packaging technology using the hidden pin type high-power LED support has the advantages of improving the productivity by 300%, reducing the LED cost to one third of the current sales price, solving the problem of high price of LEDs fundamentally, being favorable to promote the automation upgrade of the entire LED industry, and facilitating the overall popularization of LED illumination.

Preferably, each conductive pin comprises a pad and an extended portion which is bent down along the pad; the extended portion passes through the bottom surface of the base and a flanging is formed on the bottom surface of the base; the bottom surface of the flanging is parallel and level to the bottom surfaces of the heat sink and the base; and an insulating gap is reserved between the pad and the heat sink.

Preferably, the base is made of silicone resin.

Preferably, the conductive pins comprise a positive conductive pin and a negative conductive pin, and pads of the positive conductive pin and the negative conductive pin are arranged at the bottom of a cavity.

Preferably, a reflective layer is respectively arranged on the upper surfaces of the pads and the upper surface of a heat sink.

Preferably, a concave portion for receiving an LED chip is formed on the top of the heat sink.

Preferably, the width of the insulating gap is between 0.1 mm and 0.3 mm.

Preferably, the conductive pins are in the shape of a cube; a welding area is respectively arranged on the upper ends of the conductive pins; the bottom surfaces of the conductive pins are parallel and level to the bottom surfaces of the heat sink and the base; the outer side faces of the conductive pins, over against the heat sink, are parallel and level to the side face of the base; and an insulating gap is respectively reserved between the conductive pins and the heat sink.

The invention also provides a hidden pin type high-power LED packaging structure using the hidden pin type high-power LED support, wherein an LED chip is fixed on a heat sink and electrically connected with conductive pins; and packaging colloid is filled into a cavity for covering the LED chip.

The high-power LED packaging structure provided by the invention successfully hides the conductive pins extended to both sides of an imitated Lumen lamp bead in the prior art in a frame of the base and hides exposed flangings of the conductive pins at the bottom of the base, so that the subsequent automated LED production can be smoothly realized through a vibration plate. The hidden pin type high-power LED support has skillful structural design, solves the long-term technical problem in the field that the comprehensive automated production of high-power LEDs cannot be realized, completely breaks through the traditional semiautomatic high-power LED packaging mode, promotes the automated packaging process of the entire industry, and is a new revolutionary breakthrough in the field of high-power LED packaging. The high-power LED packaging structure using the hidden pin type high-power LED support has the advantages of improving the productivity by 300%, reducing the LED cost to one third of the current sales price, solving the problem of high price of LEDs fundamentally, being favorable to promote the automation upgrade of the whole LED industry, and facilitating the overall popularization of LED illumination.

Preferably, each conductive pin comprises a pad and an extended portion which is bent down along the pad; the extended portion passes through the bottom surface of the base and a flanging is formed on the bottom surface of the base; the bottom surface of the flanging is parallel and level to the bottom surfaces of the heat sink and the base; and an insulating gap is reserved between the pad and the heat sink.

Preferably, the base is made of silicone resin.

Preferably, fluorescent colloid is selected as the packaging colloid.

Preferably, the conductive pins are in the shape of a cube; a welding area is respectively arranged on the upper ends of the conductive pins; the bottom surfaces of the conductive pins are parallel and level to the bottom surfaces of the heat sink and the base; the outer side faces of the conductive pins, over against the heat sink, are parallel and level to the side face of the base; and an insulating gap is respectively reserved between the conductive pins and the heat sink.

The invention also provides packaging technology for producing the hidden pin type high-power LED, which comprises the following steps that:

firstly, an LED support is prepared and cleaned;

secondly, an LED chip is fixed on a heat sink in the LED support and roasted and is electrically connected with pads in the LED support through wires;

thirdly, packaging colloid for covering the LED chip is filled into a cavity of the LED support and roasted;

fourthly, a single LED is formed by cutting through an automatic emptying machine and transmitted to a light splitting device for light splitting through a vibration plate;

and fifthly, the LED after light splitting is transmitted to a braider for automatic braiding and subjected to external packing.

Due to the adoption of the hidden pin type high-power LED support, the high-power LED packaging technology provided by the invention successfully hides the conductive pins extended to both sides of an imitated Lumen lamp bead in the prior art in a frame of a base and hides exposed flangings of the conductive pins at the bottom of the base, consequently the subsequent automated LED production can be smoothly realized through a vibration plate. The hidden pin type high-power LED support has skillful structural design, simplifies the entire high-power LED packaging technology, solves the long-term technical problem in the field that the comprehensive automated production of high-power LEDs cannot be realized, completely breaks through the traditional semiautomatic high-power LED packaging mode, promotes the automated packaging process of the entire industry, and is a new revolutionary breakthrough in the field of high-power LED packaging. The packaging technology using the hidden pin type high-power LED support has the advantages of improving the productivity by 300%, reducing the LED cost to one third of the current sales price, solving the problem of high price of LEDs fundamentally, being favorable to promote the automation upgrade of the whole LED industry, and facilitating the overall popularization of LED illumination.

Preferably, the roasting temperature in the second step is between 120 DEG C. and 175 DEG C., and the roasting time is between 20 minutes and 30 minutes.

Preferably, the roasting temperature in the third step is between 100 DEG C. and 150 DEG C., and the roasting time is between 10 minutes and 20 minutes.

Preferably, the roasting temperature in the second step is 150 DEG C., and the roasting time is 15 minutes; and the roasting temperature in the third step is 120 DEG C., and the roasting time is 15 minutes.

Preferably, each conductive pin comprises a pad and an extended portion which is bent down along the pad; the extended portion passes through the bottom surface of the base and a flanging is formed on the bottom surface of the base; the bottom surface of the flanging is parallel and level to the bottom surfaces of the heat sink and the base; and an insulating gap is reserved between the pad and the heat sink.

Preferably, the base is made of silicone resin.

Preferably, the conductive pins are in the shape of a cube; a welding area is respectively arranged on the upper ends of the conductive pins; the bottom surfaces of the conductive pins are parallel and level to the bottom surfaces of the heat sink and the base; the outer side faces of the conductive pins, over against the heat sink, are parallel and level to the side face of the base; and an insulating gap is respectively reserved between the conductive pins and the heat sink.

### BRIEF DESCRIPTION OF THE DRAWINGS

FIG. 1 is a structural diagram of the currently available high-power LED;

FIG. 2 is a front view of the hidden pin type high-power LED support;

FIG. 3 is a structural diagram of an A-A profile in the FIG. 1;

FIG. 4 is a bottom view of the hidden pin type high-power LED support;

FIG. 5 is a structural diagram of a preferred implementation of the hidden pin type high-power LED support;

FIG. 6 is a bottom view of the preferred implementation of the hidden pin type high-power LED support;

FIG. 7 is a structural diagram of another preferred implementation of the hidden pin type high-power LED support;

FIG. 8 is a schematic diagram of the packaging structure of the invention;

FIG. 9 is a schematic diagram of a preferred implementation of the packaging structure of the invention;

FIG. 10 is a schematic diagram of another preferred implementation of the packaging structure of the invention; and

FIG. 11 is a flow chart of the packaging technology of the invention.

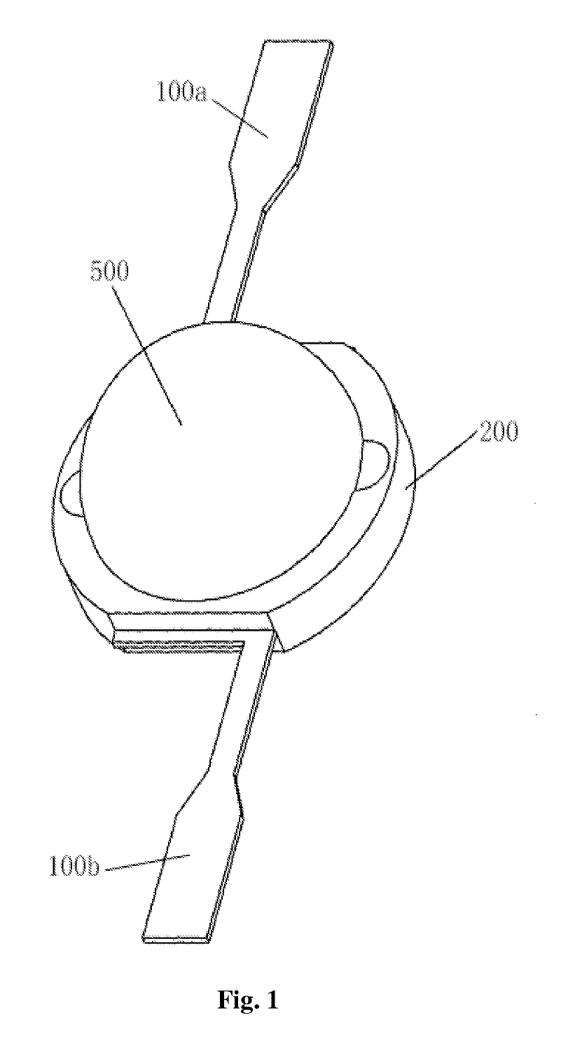

### DETAILED DESCRIPTION OF THE PREFERRED EMBODIMENTS

Further description is given to the technical proposal of the invention with the attached drawings.

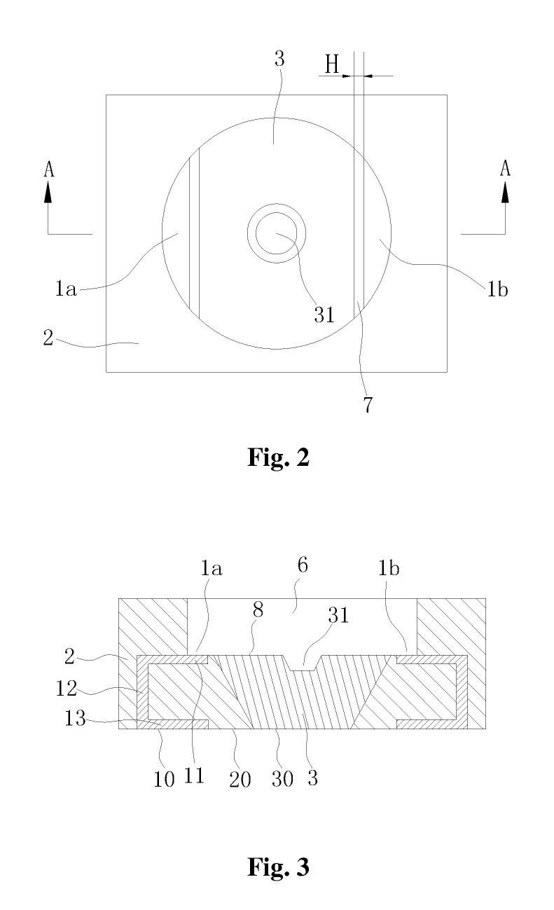

As illustrated in FIGS. 2, 3 and 4, the invention discloses a hidden pin type high-power LED support, which comprises conductive pins 1a and 1b and a base 2 for packing the conductive pins 1a and 1b; a cavity 6 is formed at the top center of the base 2; a heat sink 3 is fixedly arranged at the bottom of the cavity 6; the conductive pins 1a and 1b respectively comprise a pad 11 and an extended portion 12 which is bent down along the pad 11; the extended portion 12 passes through the bottom end face 20 of the base 2 and a flanging 13 is formed on the bottom surface 20 of the base 2; the bottom surface 10 of the flanging 13 is parallel and level to the bottom surface 30 of the heat sink 3 and the bottom surface 20 of the base 2; and an insulating gap 7 is reserved between the pad 11 and the heat sink 3.

The so-called “hidden pin type” of the invention refers to that the conductive pins 1a and 1b are hidden in a frame of the base 2. The high-power LED support provided by the invention successfully hides the conductive pins 1a and 1b extended to both sides of an imitated Lumen lamp bead in the prior art in the frame of the base 2 and hides the exposed flangings of the conductive pins 1a and 1b at the bottom of the base 2, so that the subsequent automated LED production can be realized smoothly through a vibration plate. The hidden pin type high-power LED support has skillful structural design, solves the long-term technical problem in the field that the comprehensive automated production of high-power LEDs cannot be realized, completely breaks through the traditional semiautomatic high-power LED packaging mode, promotes the automated packaging process of the entire industry, and is a new revolutionary breakthrough in the field of high-power LED packaging. The packaging technology using the hidden pin type high-power LED support has the advantages of improving the productivity by 300%, reducing the LED cost to one third of the current sales price, solving the problem of high price of LEDs fundamentally, being favorable to promote the automation upgrade of the whole LED industry, and facilitating the overall popularization of LED illumination.

The base 2 is made of silicone resin. As the silicone resin has good binding capacity with silica gel in packaging colloid, the cracking phenomenon of packaging colloid (made of silica gel) and a base (made of PPA materials) after the heating of an LED in the prior art can be prevented, and the heat resistance of products can be improved. Moreover, the silicone resin also has good light reflectivity. As for blue light, for example, the light reflectivity of the silicone resin can achieve more than 98% while the light reflectivity of the traditional base made of the PPA materials is less than 90%. Therefore, the light extraction efficiency of the LED can be improved by using the silicone resin to produce the base 2. Furthermore, the silicone resin also has good aging resistance. In the case of drive current of 60 mA, the attenuation of an LED of which a base is made of PPA materials is as high as 40% while the attenuation of an LED of which a base is made of silicone resin materials is less than 5% after the LEDs are illuminated for 3,000 hours. In addition, the silicone resin also has good UV resistance. The traditional base made of the PPA materials turns yellow after the ultraviolet radiation of 5 minutes while the appearance of the base made of the silicone resin materials is not changed after the ultraviolet radiation of 20 hours. Therefore, by adoption of the silicone resin materials to replace the traditional PPA materials first, the high-power LED support has good adhesion, high light reflectivity, excellent aging resistance and high-quality UV resistance.

The conductive pin 1a is a positive conductive pin while the conductive pin 1b is a negative conductive pin; and pads 11 of the positive conductive pin 1a and the negative conductive pin 1b are arranged at the bottom of the cavity 6 and distributed on both sides of the heat sink 3.

A reflective layer 8 is respectively arranged on the upper surfaces of the pads and the upper surface of the heat sink 3 and can be a silver coating or other kinds of metal coatings.

A concave portion 31 is formed on the top of the heat sink 3 and used for receiving an LED chip.

The heat sink 3 is in the shape of an inverted pyramid with large upper part and small lower part, so as to provide larger reflective area and improve the light extraction efficiency; the upper surface of the heat sink 3 can be rectangular; the heat sink 3 can be made of copper, aluminum, graphite, ceramics or other metal alloys such as aluminum alloy and tungsten-copper alloy.

The width H of the insulating gap 7 is between 0.1 mm and 0.3 mm and is 0.1 mm or 0.2 mm preferably, so as to provide larger reflective area and improve the light extraction efficiency.

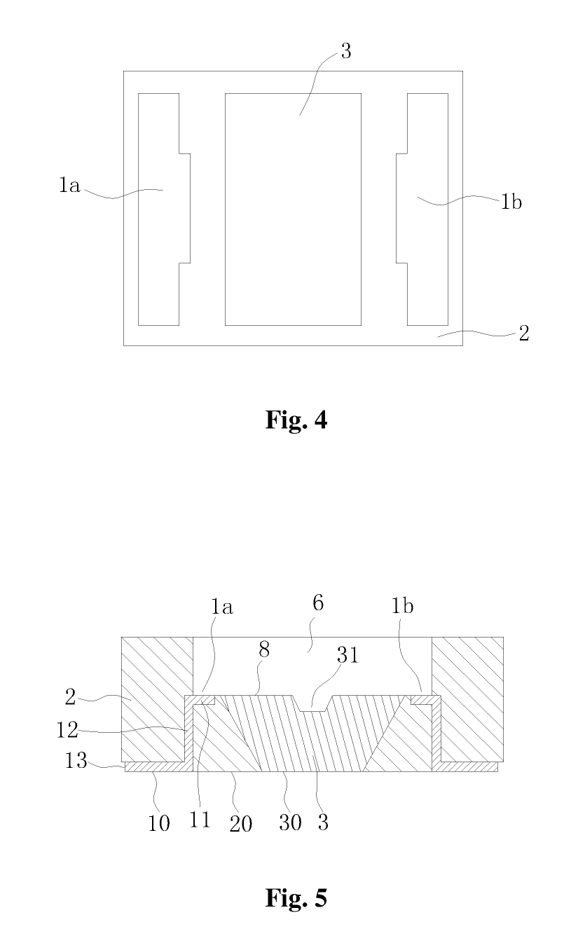

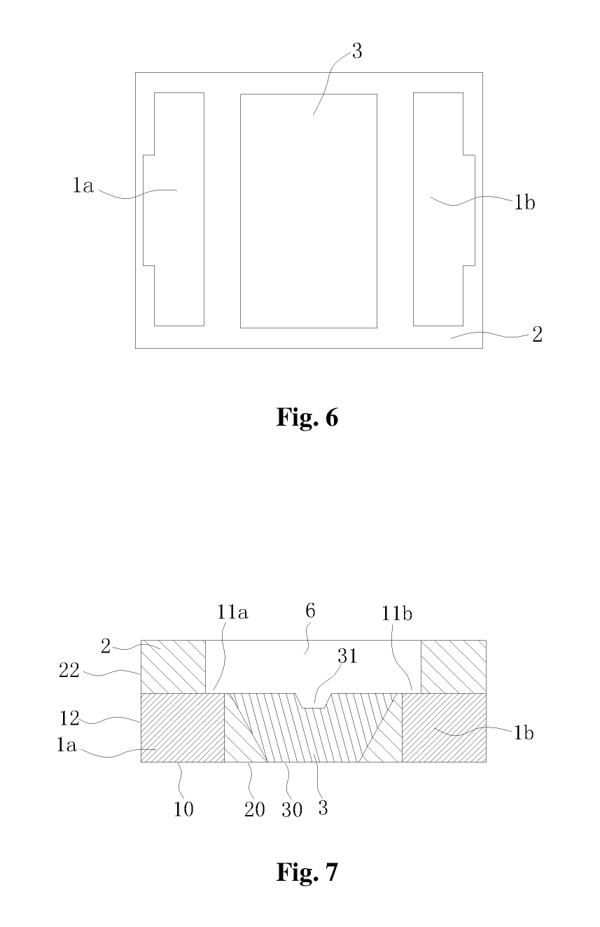

As illustrated in FIGS. 3 and 4, the flangings 13 of the conductive pins 1a and 1b can be bent to the center of the base 2 so as to achieve the aim of hiding the conductive pins 1a and 1b. As illustrated in FIGS. 5 and 6, the flangings 13 of the conductive pins 1a and 1b can also be bent to the periphery of the base 2, and the aim of hiding the conductive pins 1a and 1b can also be achieved. That is to say, the flangings 13 of the conductive pins 1a and 1b can be bent to the left or the right.

Another preferred implementation of the hidden pin type high-power LED support is illustrated in FIG. 7, namely conductive pins 1a and 1b are in the shape of a cube; a welding area is respectively arranged on the upper ends 11a and 11b of the conductive pins 1a and 1b; the bottom surfaces 10 of the conductive pins 1a and 1b are parallel and level to the bottom surface 30 of a heat sink 3 and the bottom surface 20 of a base 2; the outer side faces 12 of the conductive pins 1a and 1b, over against the heat sink 3, are parallel and level to the side face 22 of the base 2; and an insulating gap is respectively reserved between the conductive pins 1a and 1b and the heat sink 3.

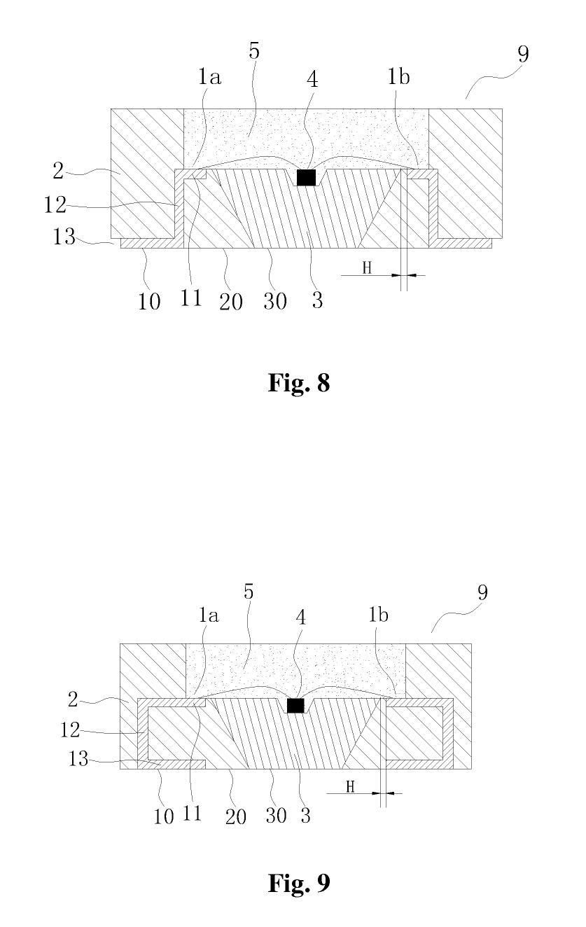

As illustrated in FIGS. 8 and 9, the invention also provides a hidden pin type high-power LED packaging structure using the hidden pin type high-power LED support, which comprises an LED support 9, an LED chip 4 fixed inside the LED support 9, and packaging colloid 5 for covering the LED chip 4, wherein the support 9 comprises conductive pins 1a and 1b and a base 2 for packing the conductive pins 1a and 1b; a cavity 6 is formed on the top of the base 2; a heat sink 3 is fixedly arranged at the bottom of the cavity 6; each conductive pin comprises a pad 11 and an extended portion 12 which is bent down along the pad; the extended portion 12 passes through the bottom surface 20 of the base 2 and a flanging 13 is formed on the bottom surface 20 of the base 2; an insulating gap 7 is reserved between the pad 11 and the heat sink 3; the LED chip 4 is fixed on the heat sink 3 and electrically connected with the pad 11; the packaging colloid 5 is filled into the cavity 6 to cover the LED chip 4; and the bottom surface 10 of the flanging 13 is parallel and level to the bottom surface 30 of the heat sink and the bottom surface 20 of the base 2, for sake of the subsequent automated light splitting of an LED lamp bead.

A concave portion 31 is formed on the top of the heat sink 3 and used for receiving the LED chip 4.

Fluorescent colloid is selected as the packaging colloid 5 and is packaging colloid uniformly mixed with fluorescent powder. The preferred LED chip 4 is a blue LED chip and the fluorescent colloid is yellow fluorescent colloid. Herein, white light can be obtained by using the blue LED chip to excite the yellow fluorescent colloid. The above is only used for explaining the embodiment of the packaging structure of the invention and is not intended to limit the scope of protection of the invention.

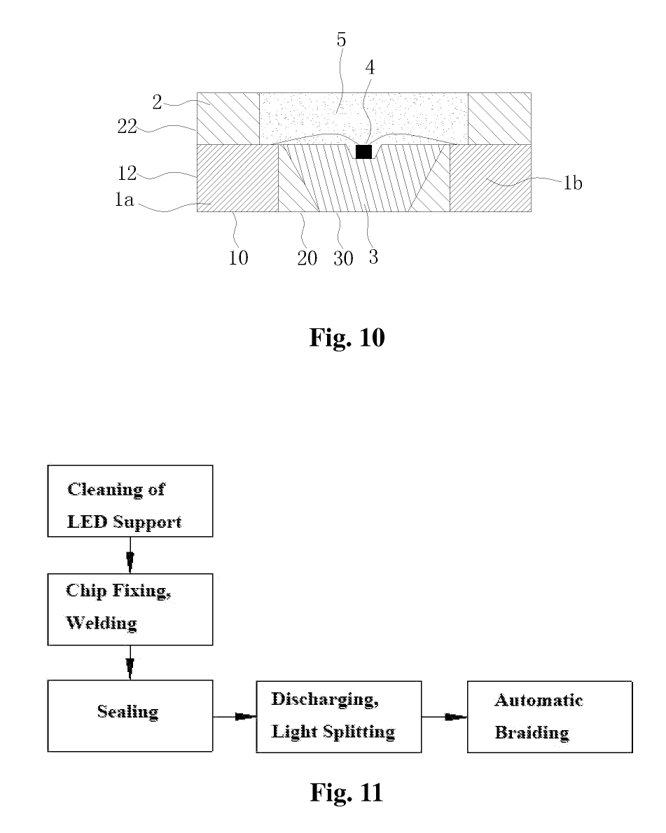

Another implementation of the packaging structure of the invention is illustrated in FIG. 10, namely conductive pins 1a and 1b are in the shape of a cube; a welding area is respectively arranged on the upper end portions 11a and 11b of the conductive pins 1a and 1b; the bottom surfaces 10 of the conductive pins 1a and 1b are parallel and level to the bottom surface 30 of a heat sink 3 and the bottom surface 20 of a base 2; the outer side faces 12 of the conductive pins 1a and 1b, over against the heat sink 3, are parallel and level to the side face 22 of the base 2; an insulating gap is respectively reserved between the conductive pins 1a and 1b and the heat sink 3; and an LED chip 4 is fixed on the heat sink 3 and covered by packaging colloid 5.

As illustrated in FIGS. 8, 9 and 11, the invention also provides packaging technology for producing the high-power LED, which comprises the following steps that:

firstly, an LED support 9 is prepared and cleaned;

secondly, an LED chip 4 is fixed on a heat sink 3 in the LED support 9 and roasted and is electrically connected with pads 11 in the LED support 9 through wires (as illustrated in FIG. 6);

thirdly, packaging colloid 5 for covering the LED chip 4 is filled into a cavity 6 of the LED support 9 and roasted;

fourthly, a single LED is formed by cutting through an automatic emptying machine and transmitted to a light splitting device for light splitting through a vibration plate;

and fifthly, the LED after light splitting is transmitted to a braider for automatic braiding and subjected to external packing.

The roasting temperature in the second step is between 120 DEG C. and 175 DEG C., and the roasting time is between 20 minutes and 30 minutes. The LED can be roasted at an increasing temperature. For example, the LED is roasted for 5 minutes at the temperature of 120 DEG C. first, roasted for 5 minutes after the temperature is raised to 130 DEG C., and finally roasted after the temperature is raised to 150 DEG C. Temporary detention of 30 seconds can be implemented among the three roasting periods so as to eliminate the internal stress, thereby improving the product yield.

The roasting temperature in the third step is between 100 DEG C. and 150 DEG C., and the roasting time is between 10 minutes and 20 minutes. The LED can be roasted at an increasing temperature. For example, the LED is roasted for 5 minutes at the temperature of 100 DEG C. first, roasted for 5 minutes after the temperature is raised to 120 DEG C., and finally roasted after the temperature is raised to 130 DEG C. Temporary detention of 20 seconds can be implemented among the three roasting periods so as to eliminate the internal stress, thereby solidifying the packaging colloid and improving the product stability.

Wherein, the preferred roasting temperature in the second step is 150 DEG C., and the preferred roasting time is 15 minutes; and the preferred roasting temperature in the third step is 120 DEG C., and the preferred roasting time is 15 minutes.

As illustrated in FIGS. 8 and 9, conductive pins 1a and 1b respectively comprise a pad 11 and an extended portion 12 which is bent down along the pad 11; the extended portion 12 passes through the bottom end face 20 of a base 2 and a flanging 13 is formed on the bottom surface 20 of the base 2; the bottom surface 10 of the flanging 13 is parallel and level to the bottom surface 30 of the heat sink 3 and the bottom surface 20 of the base 2; and an insulating gap 7 is reserved between the pad 11 and the heat sink 3. The base 2 is made of silicone resin.

Another implementation of the packaging structure of the invention is illustrated in FIG. 10, namely conductive pins 1a and 1b are in the shape of a cube; a welding area is respectively arranged on the upper end portions 11a and 11b of the conductive pins 1a and 1b; the bottom surfaces 10 of the conductive pins 1a and 1b are parallel and level to the bottom surface 30 of a heat sink 3 and the bottom surface 20 of a base 2; the outer side faces 12 of the conductive pins 1a and 1b, over against the heat sink 3, are parallel and level to the side face 22 of the base 2; an insulating gap is respectively reserved between the conductive pins 1a and 1b and the heat sink 3.

The above is only used for explaining the invention. Any simple modification and deformation made by those skilled in the art without deviating from the creative spirit of the invention shall be still within the scope of protection of the invention.

What is claimed is:

1. A hidden pin type high-power LED support, comprising conductive pins and a base for packing the conductive pins, wherein a cavity formed on the top of the base; a heat sink fixedly arranged at the bottom of the cavity; the conductive pins passing through the bottom surface of the base; and the bottom surfaces of the conductive pins being parallel and level to the bottom surfaces of the base and the heat sink.

2. The hidden pin type high-power LED support according to claim 1, wherein each conductive pin comprises a pad and an extended portion which is bent down along the pad; the extended portion passes through the bottom surface of the base and a flanging is formed on the bottom surface of the base; the bottom surface of the flanging is parallel and level to the bottom surfaces of the heat sink and the base; and an insulating gap is reserved between the pad and the heat sink.

3. The hidden pin type high-power LED support according to claim 2, wherein the base is made of silicone resin.

4. The hidden pin type high-power LED support according to claim 3, wherein the conductive pins comprise a positive conductive pin and a negative conductive pin; and pads of the positive conductive pin and the negative conductive pin are arranged at the bottom of the cavity.

5. The hidden pin type high-power LED support according to claim 4, wherein a reflective layer is respectively arranged on the upper surfaces of the pads and the upper surface of the heat sink.

6. The hidden pin type high-power LED support according to claim 5, wherein a concave portion for receiving an LED chip is formed on the top of the heat sink.

7. The hidden pin type high-power LED support according to claim 6, wherein the width of the insulating gap is between 0.1 mm and 0.3 mm.

8. The hidden pin type high-power LED support according to claim 1, wherein the conductive pins are in the shape of a cube; a welding area is respectively arranged on the upper ends of the conductive pins; the bottom surfaces of the conductive pins are parallel and level to the bottom surfaces of the heat sink and the base; the outer side faces of the conductive pins, over against the heat sink, are parallel and level to the side face of the base; and an insulating gap is respectively reserved between the conductive pins and the heat sink.

9. A hidden pin type high-power LED packaging structure using the hidden pin type high-power LED support according to claim 1, wherein an LED chip is fixedly arranged on a heat sink and electrically connected with conductive pins; and packaging colloid is filled into a cavity to cover the LED chip.

10. The hidden pin type high-power LED packaging structure according to claim 9, wherein each conductive pin comprises a pad and an extended portion which is bent down along the pad; the extended portion passes through the bottom surface of a base and a flanging is formed on the bottom surface of the base; the bottom surface of the flanging is parallel and level to the bottom surfaces of the heat sink and the base; and an insulating gap is reserved between the pad and the heat sink.

11. The hidden pin type high-power LED packaging structure according to claim 10, wherein the base is made of silicone resin.

12. The hidden pin type high-power LED packaging structure according to claim 11, wherein fluorescent colloid is selected as the packaging colloid.

13. The hidden pin type high-power LED packaging structure according to claim 12, wherein the conductive pins are in the shape of a cube; a welding area is respectively arranged on the upper ends of the conductive pins; the bottom surfaces of the conductive pins are parallel and level to the bottom surfaces of the heat sink and the base; the outer side faces of the conductive pins, over against the heat sink, are parallel and level to the side face of the base; and an insulating gap is respectively reserved between the conductive pins and the heat sink.

14. Hidden pin type high-power LED packaging technology using the hidden pin type high-power LED support according to claim 9, wherein the hidden pin type high-power LED packaging technology comprising the following steps that:
firstly, an LED support is prepared and cleaned;
secondly, an LED chip is fixed on a heat sink in the LED support and roasted and is electrically connected with pads in the LED support through wires;
thirdly, packaging colloid for covering the LED chip is filled into a cavity of the LED support and roasted;
fourthly, a single LED is formed by cutting through an automatic emptying machine and transmitted to a light splitting device for light splitting through a vibration plate;
and fifthly, the LED after light splitting is transmitted to a braider for automatic braiding and subjected to external packing.

15. The hidden pin type high-power LED packaging technology according to claim 14, wherein the roasting temperature in the second step is between 120 DEG C. and 175 DEG C., and the roasting time is between 20 minutes and 30 minutes.

16. The hidden pin type high-power LED packaging technology according to claim 15, wherein the roasting temperature in the third step is between 100 DEG C. and 150 DEG C., and the roasting time is between 10 minutes and 20 minutes.

17. The hidden pin type high-power LED packaging technology according to claim 16, wherein the roasting temperature in the second step is 150 DEG C., and the roasting time is 15 minutes; and the roasting temperature in the third step is 120 DEG C., and the roasting time is 15 minutes.

18. The hidden pin type high-power LED packaging technology according to claim 17, wherein each conductive pin comprises a pad and an extended portion which is bent down along the pad; the extended portion passes through the bottom surface of a base and a flanging is formed on the bottom surface of the base; the bottom surface of the flanging is parallel and level to the bottom surfaces of the heat sink and the base; and an insulating gap is reserved between the pad and the heat sink.

19. The hidden pin type high-power LED packaging technology according to claim 18, wherein the base is made of silicone resin.

20. The hidden pin type high-power LED packaging technology according to claim 17, wherein the conductive pins are in the shape of a cube; a welding area is respectively arranged on the upper ends of the conductive pins; the bottom surfaces of the conductive pins are parallel and level to the bottom surfaces of the heat sink and the base; the outer side faces of the conductive pins, over against the heat sink, are parallel and level to the side face of the base; and an insulating gap is respectively reserved between the conductive pins and the heat sink.
